(19) United States
(12) Patent Application Publication
(10) Pub. No.: US 2016/0149009 A1
(43) Pub. Date: May 26, 2016

(54) SEMICONDUCTOR DEVICE AND MANUFACTURING METHOD THEREOF

(71) Applicant: Kabushiki Kaisha Toshiba, Minato-ku (JP)

(72) Inventor: Hirokazu TOMINO, Yokkaichi (JP)

(73) Assignee: Kabushiki Kaisha Toshiba, Minato-ku (JP)

(21) Appl. No.: 14/642,009

(22) Filed: Mar. 9, 2015

Related U.S. Application Data
(60) Provisional application No. 62/084,402, filed on Nov. 25, 2014.

(51) Int. Cl. H01L 29/423; H01L 21/3213; H01L 21/28; H01L 29/788; H01L 29/66

(52) U.S. Cl. CPC H01L 29/42324; H01L 29/788; H01L 29/66825; H01L 21/28273; H01L 21/3213

(57) ABSTRACT

A semiconductor device according to an embodiment includes a semiconductor substrate, and a gate dielectric film is provided on the semiconductor substrate. A first gate electrode is provided on the gate dielectric film. Lower end portions of side surfaces of the first gate electrode are inclined toward a center of a channel portion. A sidewall film covers the side surfaces of the first gate electrode. A void or a low dielectric material having a dielectric constant lower than that of the sidewall film is located between the lower end portions of the side surfaces of the first gate electrode and the sidewall film.

### CROSS REFERENCE TO RELATED APPLICATIONS

This application is based upon and claims the benefit of priority from the prior U.S. Provisional Patent Application No. 62/084,402, filed on Nov. 25, 2014, the entire contents of which are incorporated herein by reference.

### FIELD

The embodiments of the present invention relate to a semiconductor device and manufacturing method thereof.

### BACKGROUND

A high voltage is sometimes applied to a source or a drain of a transistor used in a peripheral circuit and the like of a semiconductor memory during a data erase operation or the like. When a high voltage is repeatedly applied to the source or the drain of a transistor, an electric field concentrates in a gate electrode end of the transistor and charges are trapped in an oxide film near the gate electrode end in some cases. If many charges are trapped in a gate dielectric film, a threshold voltage of the transistor changes and thus it becomes difficult for the transistor to operate normally.

### BRIEF DESCRIPTION OF THE DRAWINGS

FIG. 1 is a block diagram showing an example of a configuration of a NAND flash memory including a semiconductor device 1 according to a first embodiment;

FIG. 2 is a cross-sectional view showing an example of a configuration of the semiconductor device 100 according to the first embodiment;

FIGS. 3A to 5B are schematic cross-sectional views showing an example of a manufacturing method of the semiconductor device 100 according to the first embodiment; and

FIG. 6 is a cross-sectional view showing an example of a configuration of a semiconductor device 200 according to a second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor substrate, and a gate dielectric film is provided on the semiconductor substrate. A first gate electrode is provided on the gate dielectric film. Lower end portions of side surfaces of the first gate electrode are inclined toward a center of a channel portion. A sidewall film covers the side surfaces of the first gate electrode. A void or a low dielectric material having a dielectric constant lower than that of the sidewall film is located between the lower end portions of the side surfaces of the first gate electrode and the sidewall film.

### First Embodiment

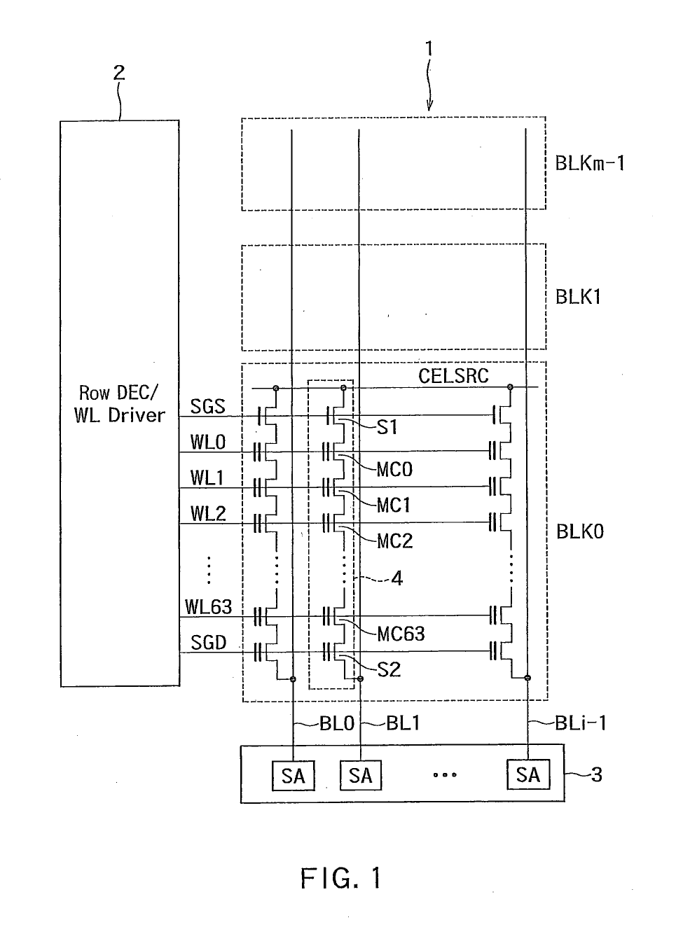

FIG. 1 is a block diagram showing an example of a configuration of a NAND flash memory including a semiconductor device 1 according to a first embodiment.

In the NAND flash memory in this example, NAND cell units (memory strings) 4 are each composed of 64 memory cells MC0 to MC63 connected in series and select gate transistors S1 and S2 connected to opposite ends of the 64 memory cells, respectively. Sources of the select gate transistors S1 are connected to a common source line CELSRC and drains of the select gate transistors S2 are connected to bit lines BL (BL0 to BLi−1), respectively. The bit lines BL can be electrically connected to the memory cells MC in the corresponding memory strings 4 via the corresponding select gate transistors S2, respectively. Control gates of the memory cells MC0 to MC63 are connected to word lines WL (WL0 to W63), respectively, and gates of the select gate transistors S1 and S2 are connected to select gate lines SGS and SGD, respectively.

A range including a plurality of memory cells MC along one word line WL corresponds to a unit (a page) of batch data read and batch data write. A range including a plurality of memory strings 4 arranged in a word line direction corresponds to a unit (a cell block BLK) of batch data erase. In FIG. 1, a plurality of cell blocks BLK0 to BLKm−1 that share the bit lines BL are arrayed in a bit line direction to constitute a cell array 1. The word lines WL and the select gate lines SGS and SGD are driven by a row decoder 2. The bit lines BL are connected to sense amplifier circuits SA, respectively, in a page buffer 3.

A semiconductor device 100 according to the first embodiment is a transistor used as the select gate transistors S1 and S2, the row decoder/WL (word line) driver 2, the sense amplifier circuits SA, peripheral circuits thereof, or the like.

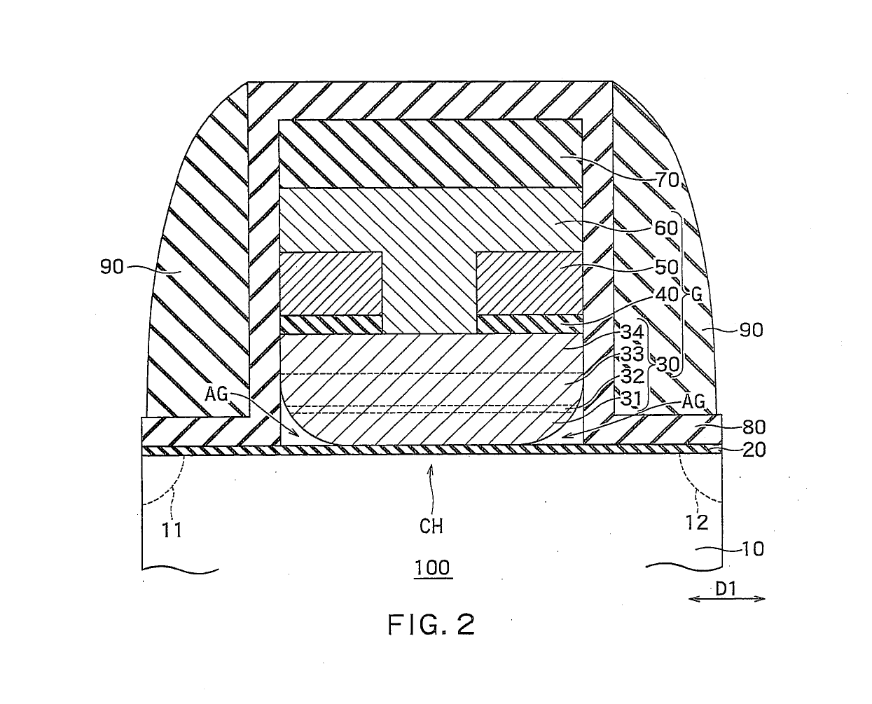

FIG. 2 is a cross-sectional view showing an example of a configuration of the semiconductor device 100 according to the first embodiment. The semiconductor device 100 includes a semiconductor substrate 10, a gate dielectric film 20, a gate electrode G, a hard mask 70, a sidewall film 80, and a spacer 90.

The semiconductor substrate 10 can be, for example, any one of a bulk silicon substrate, a SOI (Silicon On Insulator) substrate, a SON (Silicon On Nothing) substrate, a GeOI (Germanium On Insulator) substrate, a SiGe-OI (SiGe On Insulator) substrate, and a III-V compound semiconductor substrate. A source region 11 and a drain region 12 are provided in a surface of the semiconductor substrate 10. Although not shown in FIG. 2, an extension layer can be further provided in the surface of the semiconductor substrate 10.

The gate dielectric film 20 is provided on the semiconductor substrate 10. The gate dielectric film 20 is formed of, for example, a silicon dioxide film or a dielectric film having a higher dielectric constant than that of the silicon dioxide film.

The gate electrode G is provided on the gate dielectric film 20. The gate electrode G includes a first gate electrode 30, an interpoly dielectric film (intergate dielectric film) 40, a second gate electrode 50, and a third gate electrode 60.

For example, polysilicon is used as the first gate electrode 30. Lower end portions of side surfaces of the first gate electrode 30 are inclined toward a central part of a channel portion CH in a cross section along a channel length direction D1 and are formed in an inversely tapered shape. In other words, the lower end portions of the opposite side surfaces of the first gate electrode 30 are recessed toward a central part of the first gate electrode 30 in the cross section along the channel length direction D1. In still other words, the lower end portions of the opposite side surfaces of the first gate electrode 30 have an inclination toward the central part of the first gate electrode at an end on the side of the source region 11 and/or at an end on the side of the drain region 12 (at opposite ends of the first gate electrode 30 in the channel length direction D1). The lower end portions of the side surfaces of the first gate electrode 30 can be formed in a rounded curve shape as shown in FIG. 2 or in a flat surface shape (not shown).

The first gate electrode 30 further includes an electrode lower layer 31, an electrode intermediate block film 32, an electrode intermediate layer 33, and an electrode upper layer 34. The electrode lower layer 31, the electrode intermediate layer 33, and the electrode upper layer 34 are formed of, for example, polysilicon. The electrode lower layer 31 is provided on the gate dielectric film 20 and contains impurities at a relatively high concentration (first impurity concentration). The electrode intermediate layer 33 and the electrode upper layer 34 are provided above the electrode lower layer 31 and contain impurities at a relatively low concentration (second impurity concentration) lower than the first impurity concentration. The impurity concentration of the electrode upper layer 34 can be lower than that of the electrode intermediate layer 33. For example, the electrode upper layer 34 can be non-doped polysilicon.

The electrode intermediate block film 32 is provided on the electrode lower layer 31 and is located between the electrode lower layer 31 and the electrode intermediate layer 33 or the electrode upper layer 34. The electrode intermediate block film 32 is formed of an insulating film such as a silicon dioxide film. The electrode intermediate block film 32 is provided to prevent diffusion of impurities from the electrode lower layer 31 to the electrode intermediate layer 33 and the electrode upper layer 34. That is, the electrode intermediate block film 32 functions as a diffusion suppression film that suppresses diffusion of the impurities contained in the electrode lower layer 31. The thickness of the electrode intermediate block film 32 is so small that conductibility between the electrode lower layer 31 and electrode intermediate layer 33 or the electrode upper layer 34 is not impaired. In a memory cell, the first gate electrode 30 functions as a charge accumulation layer.

The interpoly dielectric film 40 is provided on a part of the layer surface of the electrode upper layer 34 of the first gate electrode 30. The interpoly dielectric film 40 is formed of an insulating film such as a silicon dioxide film. The interpoly dielectric film 40 of the semiconductor device 100 is removed at a part of the top surface of the first gate electrode 30 and enables the third gate electrode 60 to be in contact with the first gate electrode 30.

The second gate electrode 50 is provided on the interpoly dielectric film 40. The third gate electrode 60 is provided on the second gate electrode 50. The third gate electrode 60 is also provided at the part where the interpoly dielectric film 40 is not provided, thereby to be in contact with the electrode upper layer 34. A conductive material such as doped polysilicon or a metal is used as the second gate electrode 50 and the third gate electrode 60. When doped polysilicon is used as the second gate electrode 50 and the third gate electrode 60, it is preferable that the impurity concentration thereof be lower than that of the electrode lower layer 31.

As described above, in the semiconductor device 100, the second gate electrode 50 and the third gate electrode 60 are electrically connected to the first gate electrode 30. Accordingly, the first to third gate electrodes 30 to 60 function as one gate electrode G. In a memory cell, the second gate electrode 50 and the third gate electrode 60 are electrically insulated from the first gate electrode 30 by the interpoly dielectric film 40.

The hard mask 70 is provided on the third gate electrode 60. The hard mask 70 is formed of an insulating film such as a silicon dioxide film.

The sidewall film 80 covers side surfaces of the gate electrode G. At the lower end portions of the side surfaces of the first gate electrode 30, the sidewall film 80 extends substantially perpendicularly to the surface of the semiconductor substrate 10 along the side surfaces of the gate electrode G. Therefore, the sidewall film 80 is not in contact with the side surfaces of the first gate electrode 30 at the lower end portions of the side surfaces of the first gate electrode 30 and air gaps (voids) AG are provided between the sidewall film 80 and the lower end portions of the side surfaces of the first gate electrode 30. This is because the lower end portions of the side surfaces of the first gate electrode 30 in the first embodiment are inclined toward the center of the channel portion CH and have the inversely tapered shape. The sidewall film 80 is formed of an insulating film such as a silicon nitride film.

The air gaps AG are provided at least at an end in the channel length direction D1 of the lower end portions of the first gate electrode 30 (an end on the side of the source region 11 and/or an end on the side of the drain region 12). The air gaps AG have a lower dielectric constant that that of the sidewall film 80 and can be air, for example.

The spacer 90 is provided on the side surfaces of the gate electrode G with the sidewall film 80 interposed therebetween. An insulating film such as a silicon dioxide film is used as the spacer 90.

As described above, in the semiconductor device 100 according to the first embodiment, the lower end portions of the side surfaces of the first gate electrode 30 are inclined at least at an end in the channel length direction D1 (the end on the side of the source region 11 and/or the end on the side of the drain region 12) and the air gaps AG are provided at the inclined portions. This reduces a capacitance between the lower end portions of the first gate electrode 30 and the semiconductor substrate 10. That is, a capacitance between the end of the first gate electrode 30 on the side of the source region 11 and/or the end of the first gate electrode 30 on the side of the drain region 12 and the semiconductor substrate 10 is reduced. Therefore, even when a high voltage is repeatedly applied to the source region 11 or the drain region 12 during a data erase operation or the like, concentration of an electric field at the lower end portions of the gate electrode G is reduced. As a result, charges (electrons, for example) are not easily trapped in the gate dielectric film 20 at the lower end portions of the first gate electrode 30.

For example, if there is no recess at the lower end portions of the first gate electrode 30 and no air gap AG is provided thereat, an electric field concentrates in the end of the first gate electrode 30 on the side of the source region 11 and/or the end thereof on the side of the drain region 12 when a high voltage is applied to the source region 11 and/or the drain region 12 during the erase operation or the like. Accordingly, electrons are trapped in oxide films such as the gate dielectric film 20, the sidewall film 80, and the spacer 90 near the end of the first gate electrode 30 on the side of the source region 11 and/or the end thereof on the side of the drain region 12. This adversely increases a threshold voltage of the transistor. As a result, when a write operation is to be performed after the electrons are trapped, a drain voltage or a source voltage for performing the write operation is not sufficiently transferred through the transistor and writing becomes difficult. To avoid this problem, it is conceivable that the area of the source region 11 and/or the drain region 12 is enlarged to separate contacts that connect to the source region 11 or contacts that connect to the drain region 12 from the gate electrode G, thereby preventing the source voltage or the drain voltage from being intensely applied to the gate dielectric film 20, the sidewall film 80, and the spacer 90 near the end of the first gate electrode 30. However, in this case, the layout area of the semiconductor device 100 is enlarged. Furthermore, an accurate control on an impurity resistance of the channel portion CH is required to ensure an on-current of the transistor.

On, the other hand, in the semiconductor device 100 according to the first embodiment, the air gaps AG having a lower dielectric constant than those of the sidewall film 80 and the spacer 90 are provided at the lower end portions of the side surfaces of the first gate electrode 30. Therefore, concentration of an electric field in the lower end portions of the gate electrode G (the end on the side of the source region 11 and/or the end of the side of the drain region 12) is reduced and thus charges are not easily trapped in the gate dielectric film 20. As a result, the threshold voltage of the semiconductor device 100 according to the first embodiment does not largely change and stabilizes. The semiconductor device 100 according to the first embodiment thus can keep a normal operation without an enlargement in the layout area or an accurate adjustment on the impurity resistance of the channel portion CH. As described above, the semiconductor device 100 according to the first embodiment can reduce charges trapped in parts near the opposite ends of the gate dielectric film 20 and enhance the reliability.

A manufacturing method of the semiconductor device 100 according to the first embodiment is explained next.

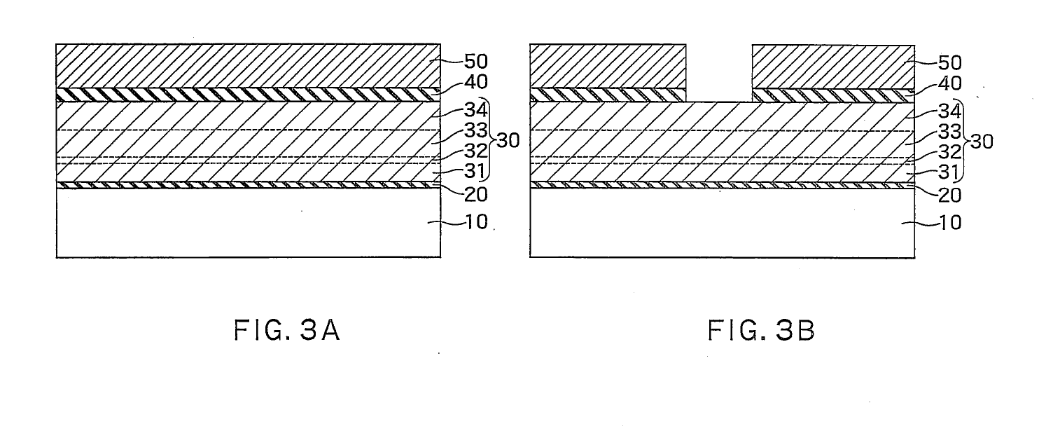

FIGS. 3A to 5B are schematic cross-sectional views showing an example of a manufacturing method of the semiconductor device 100 according to the first embodiment.

First, the gate dielectric film 20 is formed on the semiconductor substrate 10. The gate dielectric film 20 is formed of, for example, a silicon dioxide film or a high dielectric film (HfO₂, for example) having a higher dielectric constant than that of the silicon dioxide film. The semiconductor substrate 10 can be any one of a bulk silicon substrate, a SOI substrate, a SON substrate, a GeOI substrate, a SiGe-OI substrate, and a III-V compound semiconductor substrate.

Next, a material of the first gate electrode 30 is deposited on the gate dielectric film 20 by a CVD (Chemical Vapor Deposition) method or the like. The first gate electrode 30 includes the electrode lower layer 31, the electrode intermediate block film 32, the electrode intermediate layer 33, and the electrode upper layer 34 as described above. Therefore, a material of the electrode lower layer 31 is first deposited on the gate dielectric film 20. The material of the electrode lower layer 31 is, for example, doped polysilicon containing impurities at a relatively high concentration (the first impurity concentration). Subsequently, the electrode intermediate block film 32 is formed on the electrode lower layer 31. The electrode intermediate block film 32 can be formed by oxidizing a surface of the electrode lower layer 31. Alternatively, the electrode intermediate block film 32 can be deposited on the electrode lower layer 31. The electrode intermediate block film 32 is an insulating film such as a silicon dioxide film and is provided to suppress diffusion of the impurities contained in the electrode lower layer 31 to other layers 33 and 34 due to heat at the subsequent steps. Next, a material of the electrode intermediate layer 33 is deposited on the electrode intermediate block film 32. The material of the electrode intermediate layer 33 is, for example, doped polysilicon containing impurities at a concentration (the second impurity concentration) lower than that of the electrode lower layer 31. Next, a material of the electrode upper layer 34 is deposited on the electrode intermediate layer 33. For example, the material of the electrode upper layer 34 is doped polysilicon containing impurities at a concentration lower than that of the electrode intermediate layer 33 or is non-doped polysilicon. When the semiconductor device 100 is an N-type transistor, the electrode lower layer 31, the electrode intermediate layer 33, and the electrode upper layer 34 contain N-type impurities (phosphorous or arsenic, for example). When the semiconductor device 100 is a P-type transistor, the electrode lower layer 31, the electrode intermediate layer 33, and the electrode upper layer 34 contain P-type impurities (boron, for example).

Subsequently, the interpoly dielectric film 40 is formed on the electrode upper layer 34 by the CVD method or a thermal oxidization method.

Next, the second gate electrode 50 is deposited on the interpoly dielectric film 40 by the CVD method. The second gate electrode 50 is formed of a conductive material such as doped polysilicon or a metal. When doped polysilicon is used as the second gate electrode 50, it is preferable that the impurity concentration be lower than that of the electrode lower layer 31. A structure shown in FIG. 3A is thereby obtained.

Subsequently, the second gate electrode 50 and the interpoly dielectric film 40 are processed using a lithography technique and an etching technique. A part of the top surface of the first gate electrode 30 is thereby exposed as shown in FIG. 3B.

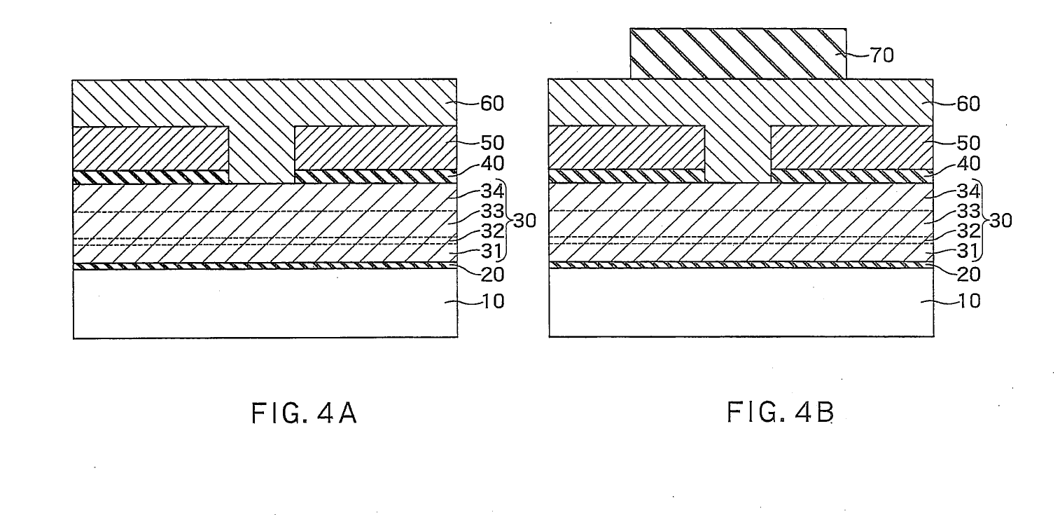

Next, the third gate electrode 60 is deposited on the first gate electrode 30 and the second gate electrode 50 by the CVD method. The third gate electrode 60 is formed of a conductive material such as doped polysilicon or a metal. When doped polysilicon is used as the third gate electrode 60, it is preferable that the impurity concentration be lower than that of the electrode lower layer 31. A structure as shown in FIG. 4A is thereby obtained.

Subsequently, a material of the hard mask 70 is deposited on the third gate electrode 60 by the CVD method. The material of the hard mask 70 is an insulating film such as a silicon dioxide film or a silicon nitride film.

Next, the material of the hard mask 70 is processed into a layout pattern of the gate electrode G by the lithography technique and the etching technique as shown in FIG. 4B.

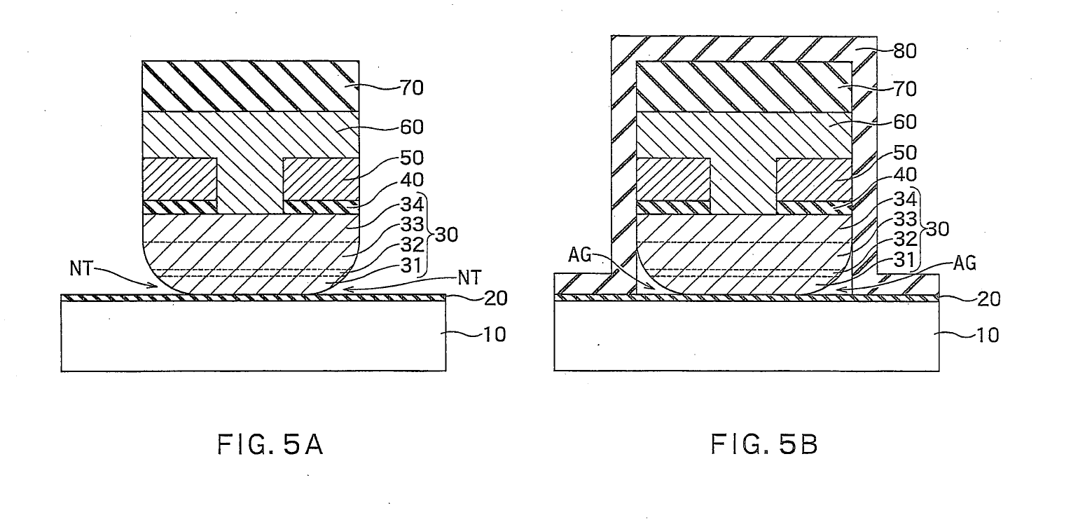

Subsequently, the third gate electrode 60, the second gate electrode 50, the interpoly dielectric film 40, and the first gate electrode 30 are etched by a RIE (Reactive Ion Etching) method using the hard mask 70 as a mask. At that time, the electrode lower layer 31 of the first gate electrode 30 has the impurities introduced at a higher concentration than those of other gate electrode parts 32 to 34, 50, and 60. Accordingly, the etching rate of the electrode lower layer 31 is higher than those of other gate electrode parts 32 to 34, 50, and 60. Therefore, the electrode lower layer 31 is largely scraped (hollowed) in a direction substantially parallel to the surface of the semiconductor substrate 10 (in a lateral direction) as shown in FIG. 5A. That is, at the time of processing the gate electrode G, the lower end portions of the side surfaces of the first gate electrode 30 are etched to be inclined in an inversely tapered shape. As a result, notches (recesses) NT are formed toward the central part of the channel portion CH at the lower end portions of the first gate electrode 30 in a cross section along the channel length direction of the channel portion CH.

Next, the sidewall film 80 is deposited to cover the side surfaces of the gate electrode G, the top surface of the hard mask 70, and the like by a plasma CVD method. At that time, the sidewall film 80 is deposited on a condition of a low embeddability. Accordingly, the sidewall film 80 is formed to leave the air gaps (voids) AG at the lower end portions of the side surfaces of the first gate electrode 30 as shown in FIG. 5B without filling the notches NT. The air gaps AG are formed between the lower end portions of the first gate electrode 30 and the sidewall film 80.

Subsequently, a material of the spacer 90 is deposited on the sidewall film 80 by the CVD method. The material of the spacer 90 is etched back by the RIE method to leave the spacer 90 at side surface portions of the gate electrode G.

Next, ion implantation for forming the source region 11 and the drain region 12 is performed using the spacer 90 as a mask. After the source region 11 and the drain region 12 are then activated by thermal treatment, an interlayer dielectric film, contact plugs, wires, and the like (not shown) are formed, whereby the semiconductor device 100 shown in FIG. 2 is completed.

As described above, according to the first embodiment, the notches (recesses) NT can be formed at the lower end portions of the opposite side surfaces of the first gate electrode 30 toward the central part of the channel portion CH using a difference in concentration of the impurities contained in the first gate electrode 30. By then forming the sidewall film 80 not to fill the notches NT, the air gaps (voids) AG can be left at the lower end portions of the opposite side surfaces of the first gate electrode 30.

In the first embodiment, the air gaps AG are formed at the lower end portions of the first gate electrode 30 in a cross section along the channel length direction of the channel portion CH. However, the air gaps AG can be also formed at lower end portions of the first gate electrode 30 in a cross section along a channel width direction of the channel portion CH. That is, the air gaps AG can be provided at all end portions (the entire outer edge) of the bottom surface of the first gate electrode 30.

### Second Embodiment

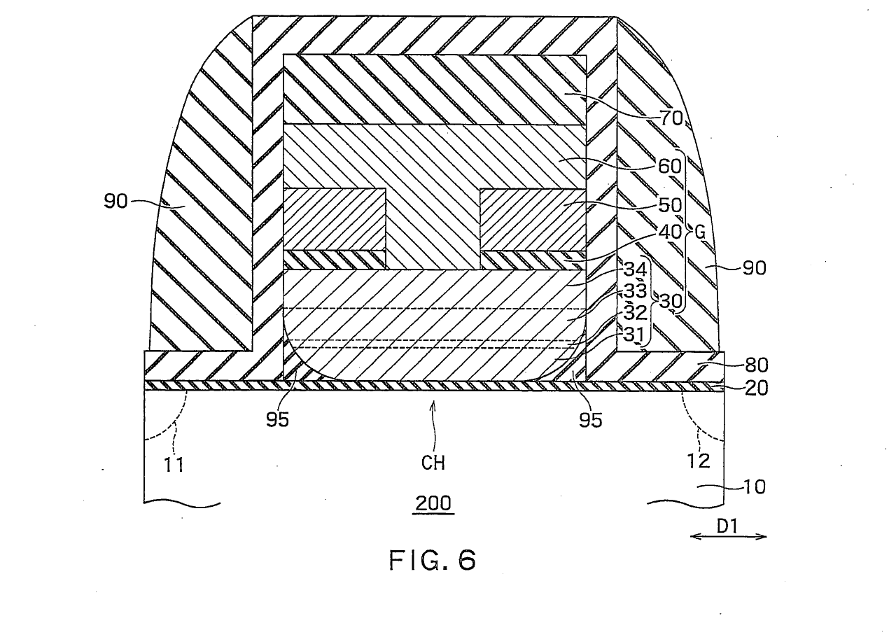

FIG. 6 is a cross-sectional view showing an example of a configuration of a semiconductor device 200 according to a second embodiment. The semiconductor device 200 has a low dielectric material 95 between the sidewall film 80 and the lower end portions of the opposite side surfaces of the first gate electrode 30. The low dielectric material 95 has a dielectric constant lower than those of the sidewall film 80 and the spacer 90 and is, for example, a SiOC film or a SiCN film formed by the plasma CVD method. Other configurations of the second embodiment can be identical to corresponding ones of the first embodiment.

The recesses at the lower end portions of the side surfaces of the first gate electrode 30 are filled with the low dielectric material 95. However, because the dielectric constant of the low dielectric material 95 is at least lower than those of the sidewall film 80 and the spacer 90, the capacitance between the lower end portions of the first gate electrode 30 in the channel length direction D1 and the semiconductor substrate 10 can be reduced. Accordingly, the second embodiment can achieve effects identical to those of the first embodiment.

It suffices that, in a manufacturing method of the semiconductor device 200 according to the second embodiment, the low dielectric material 95 is embedded in the notches (recesses) NT (see FIG. 5A) after processing the gate electrode G and before forming the sidewall film 80. Other processes in the manufacturing method of the second embodiment can be identical to corresponding ones of the first embodiment. The semiconductor device 200 according to the second embodiment can be manufactured in this way.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
a gate dielectric film on the semiconductor substrate;
a first gate electrode on the gate dielectric film, lower end portions of side surfaces of the first gate electrode being inclined toward a center of a channel portion; and
a sidewall film covering the side surfaces of the first gate electrode, wherein
a void or a low dielectric material having a dielectric constant lower than that of the sidewall film is located between the lower end portions of the side surfaces of the first gate electrode and the sidewall film.

2. The device of claim 1, wherein the lower end portions of the side surfaces of the first gate electrode are recessed toward a central part of the first gate electrode.

3. The device of claim 1, wherein the lower end portions of the side surfaces of the first gate electrode are inclined toward the center of the channel portion in a cross section along a channel length direction of the channel portion.

4. The device of claim 2, wherein the lower end portions of the side surfaces of the first gate electrode are recessed toward the central part of the first gate electrode in a cross section along a channel length direction of the channel portion.

5. The device of claim 1, wherein the first gate electrode comprises:
an electrode lower layer having a first impurity concentration on the gate dielectric film; and
an electrode upper layer having a second impurity concentration lower than the first impurity concentration above the electrode lower layer.

6. The device of claim 2, wherein the first gate electrode comprises:
an electrode lower layer having a first impurity concentration on the gate dielectric film; and
an electrode upper layer having a second impurity concentration lower than the first impurity concentration above the electrode lower layer.

7. The device of claim 5, wherein the first gate electrode further comprises an electrode intermediate layer between the electrode lower layer and the electrode upper layer.

8. The device of claim 7, wherein the first gate electrode further comprises an electrode intermediate block film between the electrode lower layer and the electrode intermediate layer, the electrode intermediate block film suppressing diffusion of impurities in the electrode lower layer.

9. The device of claim 5, further comprising:
an intergate dielectric film on a part of a top surface of the electrode upper layer;
a second gate electrode on the intergate dielectric film; and
a third gate electrode on the second gate electrode, the third gate electrode connecting to the electrode upper layer at a top surface portion of the electrode upper layer in which the intergate dielectric film is not located.

10. A manufacturing method of a semiconductor device, the method comprising:
forming a gate dielectric film on a semiconductor substrate;
forming a first gate electrode on the gate dielectric film, lower end portions of side surfaces of the first gate electrode being inclined toward a center of a channel portion; and
forming a sidewall film covering the side surfaces of the first gate electrode to provide a void at the lower end portions of the side surfaces of the first gate electrode.

11. The method of claim 10, wherein forming of the first gate electrode comprises:
forming an electrode lower layer having a first impurity concentration on the gate dielectric film;
forming an electrode upper layer having a second impurity concentration lower than the first impurity concentration above the electrode lower layer; and
etching the electrode upper layer and the electrode lower layer into a pattern of the first gate electrode.

12. The method of claim 11, wherein forming of the first gate electrode further comprises forming an electrode intermediate layer on the electrode lower layer after forming the electrode lower layer and before forming the electrode upper layer.

13. The method of claim 11, wherein an inclination of the lower end portions of the side surfaces of the first gate electrode is formed on side surfaces of the electrode lower layer.

14. The method of claim 12, wherein an inclination of the side surfaces of the first gate electrode is formed on side surfaces of the electrode lower layer.

15. The method of claim 10, wherein the lower end portions of the side surfaces of the first gate electrode are recessed toward a central part of the first gate electrode.

16. The method of claim 10, wherein the lower end portions of the side surfaces of the first gate electrode are inclined toward the center of the channel portion in a cross section along a channel length direction of the channel portion.
